(19) United States
(12) Patent Application Publication
(10) Pub. No.: US 2026/0198235 A1
(43) Pub. Date: Jul. 9, 2026

(54) TEMPORAL KERNEL DEVICE, TEMPORAL KERNEL COMPUTING SYSTEM, AND OPERATION METHODS THEREOF

(71) Applicant: Seoul National University R&DB foundation, Seoul (KR)

(72) Inventors: Cheol Seong Hwang, Seoul (KR); Yoon Ho Jang, Seoul (KR); Sung Keun Shim, Seoul (KR)

(21) Appl. No.: 18/728,846

(22) PCT Filed: Mar. 21, 2024
(86) PCT No.: PCT/KR2024/095598

§ 371 Date: Mar. 30, 2026

(30) Foreign Application Priority Data
Aug. 29, 2023 (KR) 10-2023-0113791

(51) Int. Cl. H10N 70/00; H10B 63/00

(52) U.S. Cl. CPC H10N 70/826; H10B 63/84

(57) ABSTRACT

Disclosed is a temporal kernel device including one or more temporal kernel cell structures, each of the temporal kernel cell structures may include a first nonvolatile memristor, and a second nonvolatile memristor and a capacitor connected in parallel with each other, wherein the second nonvolatile memristor and the capacitor connected in parallel with each other may be connected in series with the first nonvolatile memristor.

### TECHNICAL FIELD

The present invention relates to kernel-related devices and systems, and more particularly, to a temporal kernel device, a temporal kernel computing system including the same, and operation methods therefor.

### BACKGROUND ART

In a computer science, the kernel is a computer program which is the core of a computer operating system, and it controls the system as a whole and provides various services necessary for the execution of application programs. In the field of artificial intelligence, which has recently been attracting attention, the kernel may play a role to pre-process the signals inputted to an artificial neural network. In particular, a temporal kernel refers to a kernel which may process data in time series.

As an existing temporal kernel device, a reservoir computing device is used. The reservoir computing device includes a volatile memristor in a unit cell structure and is configured to process input signals over time by using the volatile characteristics of the memristor. However, the existing memristor-based reservoir computing systems is facing controllability issues due to the inherent fixed relaxation dynamics of a given material. In other words, in connection with the temporal kernel based on the volatile memristor, since relaxation of the conductance state of the memristor is based on material properties, there are limitations that the speed may not be controlled and other dynamics other than relaxation may not be implemented. Therefore, there is a problem that it is difficult to control the temporal characteristics of the reservoir.

In addition, in the case of the previously proposed memristive RC (resistor-capacitor) system, there are inherent limitations in implementing higher-dimensional reservoirs due to the architecture in which one input signal is mapped to one memristor. In order to improve the diversity of reservoir states in physical reservoir computing systems, two approaches such as device-to-device variation (D2D variation) and virtual nodes may be used. However, D2D fluctuations are almost uncontrollable and there are limits in effectively improving reservoir richness. This problem occurs because D2D variation-based reservoirs do not significantly improve reservoir performance by generating highly correlated dimensions, but instead increase training parameters. On the other hand, the virtual node method may have good performance, but because it performs sequential operations, it has a problem that a buffer memory to store temporal results is required.

### DISCLOSURE OF THE INVENTION

### Technical Problem

The technological object to be achieved by the present invention is to provide a temporal kernel device which may achieve high dimensional data mapping and tunable dynamics.

In addition, the technological object to be achieved by the present invention is to provide a temporal kernel device which may improve the diversity of the reservoir state and may perform efficient and accurate data processing with high dimensionality and tunable dynamics without unnecessarily increasing training parameters or relying on sequential operations.

Furthermore, the technological object to be achieved by the present invention is to provide a temporal kernel computing system including the above-described temporal kernel device.

In addition, the technological object to be achieved by the present invention is to provide operation methods of the temporal kernel device and the temporal kernel computing system.

The object to be solved by the present invention is not limited to the objects mentioned above, and other objects not mentioned will be understood by those skilled in the art from the description below.

### Technical Solution

According to one embodiment of the present invention, there is provided a temporal kernel device comprising one or more temporal kernel cell structures, wherein each of the temporal kernel cell structures includes a first nonvolatile memristor; and a second nonvolatile memristor and a capacitor connected in parallel with each other, and wherein the second nonvolatile memristor and the capacitor connected in parallel with each other are connected in series with the first nonvolatile memristor.

The temporal kernel device may include a first electrode, a second electrode, an intermediate electrode, and a third electrode, the capacitor may be disposed between the first electrode and the intermediate electrode, the second nonvolatile memristor may be disposed between the second electrode and the intermediate electrode, and the first nonvolatile memristor may be disposed between the intermediate electrode and the third electrode.

The temporal kernel device may be configured so that an electrical signal corresponding to a time-series input signal may be applied to the third electrode while the first and second electrodes are grounded.

A plurality of the temporal kernel cell structures may be arranged to form an array, and the temporal kernel device may include first and second electrodes spaced apart from each other and extending in a first direction, a plurality of third electrodes spaced apart from the first and second electrodes and extending in a second direction crossing the first and second electrodes, and a plurality of intermediate electrodes disposed between an electrode group consisting of the first and second electrodes and the plurality of third electrodes to correspond to the plurality of third electrodes, respectively. The plurality of temporal kernel cell structures may be disposed between the electrode group consisting of the first and second electrodes and the plurality of third electrodes, respectively, and each of the temporal kernel cell structures may include the capacitor disposed between the first electrode and the intermediate electrode, the second nonvolatile memristor disposed between the second electrode and the intermediate electrode, and the first nonvolatile memristor disposed between the intermediate electrode and the third electrode.

The first and second nonvolatile memristors may be arranged on the same vertical axis, and the capacitor may be arranged to be spaced apart from the second nonvolatile memristor in a horizontal direction.

The first and second nonvolatile memristors may be configured to store different information for the same input signal.

The temporal kernel device may be configured to store information in the first and second nonvolatile memristors and to input the information stored in the first and second nonvolatile memristors to an artificial neural network.

According to another embodiment of the present invention, there is provided a temporal kernel computing system including the above-described temporal kernel device; and an artificial neural network connected to the temporal kernel device and receiving information processed by the temporal kernel device.

According to another embodiment of the present invention, there is provided an operation method of a temporal kernel device comprising one or more temporal kernel cell structures, wherein each of the temporal kernel cell structures includes a first nonvolatile memristor, and a second nonvolatile memristor and a capacitor connected in parallel with each other, and wherein the second nonvolatile memristor and the capacitor connected in parallel with each other are connected in series with the first nonvolatile memristor, the method comprising: storing information in the first and second nonvolatile memristors by applying a time-series input signal to the temporal kernel cell structure; and reading information stored in the first and second nonvolatile memristors.

The temporal kernel device may include a first electrode, a second electrode, an intermediate electrode, and a third electrode, the capacitor may be disposed between the first electrode and the intermediate electrode, the second nonvolatile memristor may be disposed between the second electrode and the intermediate electrode, and the first nonvolatile memristor may be disposed between the intermediate electrode and the third electrode.

The storing information in the first and second nonvolatile memristors may include applying an electrical signal corresponding to the time-series input signal to the third electrode while the first and second electrodes are grounded.

The reading information stored in the first and second nonvolatile memristors may include applying an electrical signal for reading information stored in the first nonvolatile memristor between the third electrode and the intermediate electrode, and applying an electrical signal for reading information stored in the second nonvolatile memristor between the intermediate electrode and the second electrode.

A plurality of the temporal kernel cell structures may be arranged to form an array, and the temporal kernel device may include first and second electrodes spaced apart from each other and extending in a first direction, a plurality of third electrodes spaced apart from the first and second electrodes and extending in a second direction crossing the first and second electrodes, and a plurality of intermediate electrodes disposed between an electrode group consisting of the first and second electrodes and the plurality of third electrodes to correspond to the plurality of third electrodes, respectively. Furthermore, the plurality of temporal kernel cell structures may be disposed between the electrode group consisting of the first and second electrodes and the plurality of third electrodes, respectively and each of the temporal kernel cell structures may include the capacitor disposed between the first electrode and the intermediate electrode, the second nonvolatile memristor disposed between the second electrode and the intermediate electrode, and the first nonvolatile memristor disposed between the intermediate electrode and the third electrode.

### Advantageous Effects

According to embodiments of the present invention, it is possible to implement a temporal kernel device which may achieve high-dimensional data mapping and tunable dynamics by using a 2M (memristor)-1C (capacitor) temporal kernel cell structure including two nonvolatile memristors and one capacitor. According to embodiments of the present invention, it is possible to provide a temporal kernel device which may improve the diversity of reservoir states and perform efficient and accurate data processing with high dimensionality and tunable dynamics without unnecessarily increasing training parameters or relying on sequential operations.

In particular, according to embodiments of the present invention, since two nonvolatile memristors may perform unrelated (i.e., uncorrelated) individualized dimensional data mapping for the same input signal, the dimension of data mapping may increase and accuracy and efficiency of data processing may be improved. Furthermore, if necessary, the time constant may be easily adjusted by adjusting the size of the capacitor or adjusting the initial resistance values of the two nonvolatile memristors. Furthermore, since the mapping signal may be varied by adjusting the pulse shape of the input signal, utilization freedom degree of the device may be improved.

According to one embodiment, the complementary features projected on each memristor reflect the features of the binary pattern of the input signal, and the embodiments using 8-bit and 28-bit may exhibit an accuracy of about 94.3% or more and about 86.4% or more in the Modified National Institute of Standards and Technology (MNIST) classification task. Furthermore, according to one embodiment, for Mackey-Glass nonlinear timeseries patterns, since the temporal kernel device may exhibit a normalized root mean square error (NRMSE) of 0.04 at the minimum network size (20×1), it may be said that excellent prediction performance has been verified.

When applying the temporal kernel devices according to the above-described embodiments, it is possible to implement a temporal kernel computing system which has excellent performance and may be applied to various fields.

However, the effects of the present invention are not limited to the above effects and may be expanded in various ways without departing from the technological spirit and scope of the present invention.

### BRIEF DESCRIPTION OF THE DRAWINGS

FIG. 1 is a diagram illustrating a temporal kernel device according to an embodiment of the present invention, and a temporal kernel computing system including the same.

FIG. 2 is a diagram illustrating a change in the voltage applied to the first and second nonvolatile memristors and a change in conductance of each memristor according to the application of a temporal signal to the temporal kernel cell structure of the temporal kernel device according to an embodiment of the present invention.

FIG. 3 is a circuit diagram for explaining an operation principle of a temporal kernel device according to an embodiment of the present invention.

FIG. 4 is a diagram showing the overall operation method of a temporal kernel computing system including a temporal kernel device according to an embodiment of the present invention.

FIG. 5 is a diagram showing an optical microscope image (left image) of a temporal kernel device and a cross-sectional scanning electron microscope (SEM) image (right image) of a temporal kernel cell structure according to an embodiment of the present invention.

FIG. 6 is a diagram showing a cross-sectional transmission electron microscope (TEM) image of a first nonvolatile memristor, a second nonvolatile memristor, and a capacitor which may be applied to a temporal kernel device according to an embodiment of the present invention.

FIG. 7 is a diagram showing energy dispersive spectrometer (EDS) line profiles of a first nonvolatile memristor, a second nonvolatile memristor, and a capacitor which may be applied to a temporal kernel device according to an embodiment of the present invention.

FIG. 8 is a graph illustrating voltage-current characteristics of the first and second nonvolatile memristors which may be applied to a temporal kernel device according to an embodiment of the present invention.

FIG. 9 is a graph showing the results obtained by measuring the final conductance after applying ten voltage pulses to the first and second nonvolatile memristors which may be applied to the temporal kernel device according to an embodiment of the present invention.

FIG. 10 is a graph showing capacitance values within a predetermined voltage range according to the feature size F of the capacitor which may be applied to the temporal kernel device according to an embodiment of the present invention.

FIG. 11 to FIG. 13 are diagrams showing a change in the voltage applied to the first and second nonvolatile memristors and a change in conductance of each memristor according to the application of an input signal to the temporal kernel device according to an embodiment of the present invention.

FIG. 14 is a diagram showing the final conductance state measured in the first and second nonvolatile memristors for 16 cases of 4-bit patterns from ‘0000’ to ‘1111’ according to an embodiment of the present invention.

FIG. 15 is a schematic diagram illustrating an image inference process using a temporal kernel computing system including a temporal kernel device according to an embodiment of the present invention.

FIG. 16 is a graph showing the maximum accuracy and input network size achieved under the condition of each input sequence when image inference is performed using a temporal kernel computing system including a temporal kernel device according to an embodiment of the present invention.

FIG. 17 is a diagram showing the results of initialization and prediction by using only the conductance vector of the first nonvolatile memristor in Mackey-Glass time series prediction according to a comparative example.

FIG. 18 is a graph showing the results of initialization and prediction performed by using only the conductance vector of the second nonvolatile memristor in Mackey-Glass time series prediction according to a comparative example.

FIG. 19 is a graph showing the results obtained by performing initialization and prediction by using both of the conductance vector of the first nonvolatile memristor and the conductance vector of the second nonvolatile memristor in Mackey-Glass time series prediction, according to an embodiment of the present invention.

FIG. 20 is a diagram illustrating the results obtained by evaluating the conductance values for four types of time series patterns to analyze information extracted from the time series of the first and second nonvolatile memristors according to an embodiment of the present invention.

### BEST MODE FOR CARRYING OUT THE INVENTION

Hereinafter, embodiments of the present invention will be described in detail with reference to the accompanying drawings.

The embodiments of the present invention to be described below are provided to more clearly explain the present invention to those skilled in the art, and the scope of the present invention is not limited by the following embodiments, and the embodiments may be modified in many different forms.

The terms used in this specification are used to describe specific embodiments and are not intended to limit the present invention. The terms indicating a singular form used herein may include plural forms unless the context clearly indicates otherwise. Also, as used herein, the terms, “comprise” and/or “comprising” specify the presence of the stated shape, step, number, operation, member, element, and/or group thereof and does not exclude the presence or addition of one or more other shapes, steps, numbers, operations, elements, elements and/or groups thereof. In addition, the term, “connection” used in this specification means not only a direct connection of certain members, but also a concept including an indirect connection in which other members are interposed between the members.

In addition, in the present specification, when a member is said to be located “on” another member, this arrangement includes not only a case in which a member is in contact with another member, but also a case where another member exists between the two members. As used herein, the term, “and/or” includes any one and all combinations of one or more of the listed items. In addition, the terms of degree such as “about” and “substantially” used in the present specification are used as a range of values or degrees, or as a meaning close thereto, taking into account inherent manufacturing and substance tolerances, and exact or absolute numbers provided to aid in the understanding of this application are used to prevent the infringers from unfairly exploiting the stated disclosure.

Hereinafter, embodiments of the present invention will be described in detail with reference to the accompanying drawings. A size or a thickness of areas or parts shown in the accompanying drawings may be slightly exaggerated for clarity of the specification and convenience of description. The same reference numbers indicate the same configuring elements throughout the detailed description.

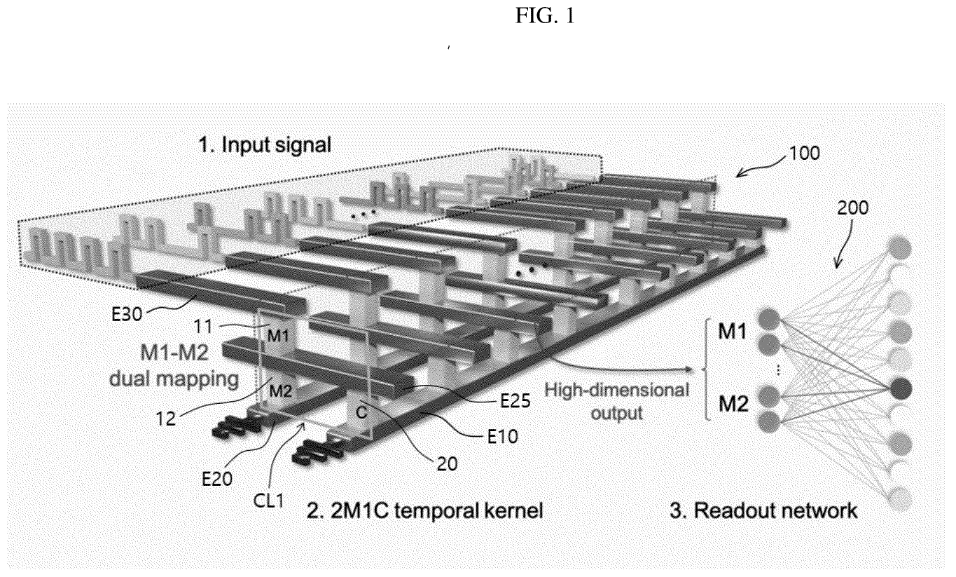

FIG. 1 is a diagram illustrating a temporal kernel device according to an embodiment of the present invention, and a temporal kernel computing system including the same. The temporal kernel device may be said to be a hardware temporal kernel device.

Referring to FIG. 1, the temporal kernel device 100 according to an embodiment of the present invention may include one or more temporal kernel cell structure CL1. The temporal kernel cell structure CL1 may include a first nonvolatile memristor 11, and a second nonvolatile memristor 12 and a capacitor 20 connected in parallel to each other, wherein the second nonvolatile memristor 12 and the capacitor 20 connected in parallel may be connected in series to the first nonvolatile memristor 11. The temporal kernel cell structure CL1 may be said to have a 2M-1C configuration. Here, M represents the nonvolatile memristors 11 and 12, and C represents the capacitor 20. The temporal kernel device 100 may be an integrated temporal kernel device having a 2M-1C cell configuration.

Each of the first and second nonvolatile memristors 11 and 12 may include two electrodes (e.g., a lower electrode and an upper electrode) and a resistance change material layer (a resistance change memory layer) disposed between them. For example, each of the first and second nonvolatile memristors 11 and 12 may have a TiN/HfO₂/W structure, where TiN may correspond to the lower electrode (or upper electrode), W (tungsten) may correspond to the upper electrode (or lower electrode) and HfO₂ may correspond to a resistance change material layer, respectively. However, this is only an example, and the specific structures and the constituent materials of the first and second nonvolatile memristors 11 and 12 may vary. The structures and the materials of existing nonvolatile memristors may be applied to the first and second nonvolatile memristors 11 and 12. The first and second nonvolatile memristors 11 and 12 may have the same stacked structure, but in some cases, they may have different stacked structures.

The capacitor 20 may include two electrodes (e.g., a lower electrode and an upper electrode) and a dielectric layer disposed between them. For example, the capacitor 20 may have a TiN/ZrO₂/Al₂O₃/ZrO₂/TiN structure, where TiN may correspond to the lower electrode and the upper electrode, and ZrO₂/Al₂O₃/ZrO₂ may correspond to the dielectric layer, respectively. ZnO₂ may play a role in increasing the dielectric constant, and Al₂O₃ may play a role in suppressing leakage current. Therefore, if a dielectric layer having ZrO₂/Al₂O₃/ZrO₂ structure is used, the capacitor 20 having a high dielectric constant and low leakage current may be manufactured. However, the specific structure and constituent materials of the capacitor 20 illustrated here are merely illustrative and may vary depending on the case. The structures and materials of existing capacitors may be applied to the capacitor 20.

The capacitor 20 is shown as a single capacitor element (capacitor device), but may include multiple capacitor elements in some cases. In other words, it may be understood that the capacitor 20 may include one capacitor element or a plurality of capacitor elements. When the capacitor 20 includes the plurality of capacitor elements, at least one of the plurality of capacitor elements may be selectively used.

The temporal kernel device 100 may include a first electrode E10, a second electrode E20, an intermediate electrode E25, and a third electrode E30. The capacitor 20 may be disposed between the first electrode E10 and the intermediate electrode E25, and the second nonvolatile memristor 12 may be disposed between the second electrode E20 and the intermediate electrode E25. The first nonvolatile memristor 11 may be disposed between the intermediate electrode E25 and the third electrode E30. Accordingly, the first nonvolatile memristor 11 and the second nonvolatile memristor 12 may be connected in series through the intermediate electrode E25, and similarly, the first nonvolatile memristor 11 and the capacitor 20 may be connected in series through the intermediate electrode E25. Furthermore, the second nonvolatile memristor 12 and the capacitor 20 may be connected in parallel to the first nonvolatile memristor 11 through the intermediate electrode E25. The intermediate electrode E25 may be referred to as a bridge electrode connecting the second nonvolatile memristor 12 and the capacitor 20. It may be understood that the temporal kernel cell structure CL1 may be considered to include the first nonvolatile memristor 11, the second nonvolatile memristor 12, the capacitor 20 and the intermediate electrode E25, and it may be understood that the first and second electrodes E10 and E20 are connected to one end of the temporal kernel cell structure CL1, and the third electrode E30 is connected to the other end of the temporal kernel cell structure CL1. In some cases, at least a portion of the first and second electrodes E10 and E20 and/or at least a portion of the third electrode E30 may also be considered to be included in the temporal kernel cell structure CL1.

A plurality of temporal kernel cell structures CL1 may be arranged. In other words, a plurality of temporal kernel cell structures CL1 may be arranged to form an array. At this time, the temporal kernel device 100 may include the first and second electrodes E10 and E20 which are spaced apart from each other (e.g., spaced apart in a horizontal direction) and extend in a first direction, the plurality of third electrodes E30 extending in a second direction which is spaced apart (e.g., spaced upward) from the first and second electrodes E10 and E20 and extend in a second direction crossing/intersecting (e.g., orthogonally crossing) the first and second electrodes E10 and E20, and the plurality of intermediate electrodes E25 disposed between an electrode group consisting of the first and second electrodes E10, E20 and the plurality of third electrodes E30 to correspond to the plurality of third electrodes E30, respectively. The plurality of intermediate electrodes E25 may extend in the second direction.

The plurality of temporal kernel cell structures CL1 may be disposed between the electrode group consisting of the first and second electrodes E10 and E20 and the plurality of third electrodes E30, respectively. The plurality of temporal kernel cell structures CL1 may be disposed at intersections of the electrode group consisting of the first and second electrodes E10 and E20 and the plurality of third electrodes E30, respectively. Accordingly, the plurality of temporal kernel cell structures CL1 spaced apart from each other in a direction parallel to the electrode group may be disposed on the electrode group consisting of the first and second electrodes E10 and E20, and the third electrode E30 connected to (in contact with) the temporal kernel cell structure CL1 may be disposed on each of the temporal kernel cell structure CL1. Each of the temporal kernel cell structures CL1 may include the capacitor 20 disposed between the first electrode E10 and the intermediate electrode E25, the second nonvolatile memristor 12 disposed between the second electrode E20 and the intermediate electrode E25, and the first nonvolatile memristor 11 disposed between the intermediate electrode E25 and the third electrode E30. Here, the case where one first electrode E10 and one second electrode E20 are used is shown, but the electrode group consisting of the first and second electrodes E10 and E20 may be arranged as plural form, a plurality of the temporal kernel cell structures CL1 and a plurality of third electrodes E30 may be disposed on each electrode group. Furthermore, the device stack from the electrode group consisting of the first and second electrodes E10 and E20 to the third electrode E30 may be upside down. A portion of the first electrode E10 may be included in the capacitor 20, and a portion of the intermediate electrode E25 may also be included in the capacitor 20. A portion of the second electrode E20 may be included in the second nonvolatile memristor 12, and a portion of the intermediate electrode E25 may also be included in the second nonvolatile memristor 12. A portion of the intermediate electrode E25 may be included in the first nonvolatile memristor 11, and a portion of the third electrode E30 may also be included in the first nonvolatile memristor 11.

When inputting data to the temporal kernel device 100, an electrical signal corresponding to a time-series input signal (e.g., an input signal which changes with time) may be applied to the third electrode E30 while the first and second electrodes E10 and E20 are grounded. In other words, when storing information in the first and second nonvolatile memristors 11 and 12 of the temporal kernel cell structure CL1, an electrical signal corresponding to a time-series input signal may be applied to the third electrode E30 while the first and second electrodes E10 and E20 are grounded. At this time, the intermediate electrode E25 may be in a floating state. In a step for storing information in the temporal kernel device 100, the electrical signal may be applied to the plurality of third electrodes E30 while the first and second electrodes E10 and E20 are grounded. Information may be stored in the first and second nonvolatile memristors 11 and 12 of each of the plurality of temporal kernel cell structures CL1 through this step.

Meanwhile, in a step for reading information stored in the first and second nonvolatile memristors 11 and 12, an electrical signal for reading information stored in the first nonvolatile memristor 11 may be applied between the third electrode E30 and the intermediate electrode E25, and an electrical signal for reading information stored in the second nonvolatile memristor 12 may be applied between the intermediate electrode E25 and the second electrode E20. When applying an electrical signal for reading information stored in the first nonvolatile memristor 11 between the third electrode E30 and the intermediate electrode E25, the second electrode E20 may be in a floating state. Similarly, when applying an electrical signal for reading information stored in the second nonvolatile memristor 12 between the intermediate electrode E25 and the second electrode E20, the third electrode E30 may be in a floating state. Furthermore, in a step for reading information stored in the first and second nonvolatile memristors 11 and 12, the first electrode E10 may be in a floating state. The influence of the capacitor 20 on the reading may be excluded by separately forming the first electrode E10 and the second electrode E20 connected to the capacitor 20 and the second nonvolatile memristor 12, respectively, under the capacitor 20 and the second non-volatile memristor 12. Therefore, a problem such as RC delay during reading may be prevented. The electrical signal for reading the information may be, for example, a direct current (DC) voltage signal, and the information may be read by measuring (sensing) the magnitude of the current flowing through the nonvolatile memristors 11 and 12 when applying the direct current (DC) voltage signal.

According to one embodiment, the first nonvolatile memristor 11 and the second nonvolatile memristor 12 may be disposed on the same (or substantially the same) vertical axis in the temporal kernel cell structure CL1, and the capacitor 20 may be arranged to be spaced apart from the second nonvolatile memristor 12 in a horizontal direction. The capacitor 20 may be disposed at the same level (height) or substantially at the same level (height) as the second nonvolatile memristor 12. In this case, manufacturing of the temporal kernel device 100 may be easy and may be advantageous in improving space efficiency and integration degree. However, the arrangement relationship of the first nonvolatile memristor 11, the second nonvolatile memristor 12, and the capacitor 20 in the temporal kernel cell structure CL1 is not limited to the above descriptions, and may change depending on the case.

The temporal kernel device 100 according to an embodiment of the present invention may have the temporal kernel cell structure CL1 having the above-described 2M-1C configuration, and in this temporal kernel cell structure CL1, information stored in the first and second nonvolatile memristors 11 and 12 may be different due to the influence of the capacitor 20. That is, the first and second nonvolatile memristors 11 and 12 may store different information for the same input signal (time-series input signal). More specifically, after the capacitor 20 is discharged by a low signal, when a high signal enters the temporal kernel cell structure CL1, a spike signal (voltage spike) may occur in the first nonvolatile memristor 11. Therefore, it may be understood that the first nonvolatile memristor 11 mainly reflects the number of transitions from a low signal to a high signal, and related characteristics in response to an input signal in which low signals and high signals are randomly repeated. Meanwhile, since the second nonvolatile memristor 12 is mainly affected by the number of high signal inputs in a different way from the first nonvolatile memristor 11, it may reflect the number of high signals and related characteristics in response to the input signal. Since the first and second nonvolatile memristors 11 and 12 may perform unrelated (i.e., uncorrelated) individualized dimensional data mapping for the same input signal, the dimension of data mapping may be increased, and the accuracy and efficiency of data processing may be improved. According to embodiments of the present invention, it is possible to implement a temporal kernel device which may improve diversity of reservoir states and may perform efficient and accurate data processing with high dimensionality and tunable dynamics without unnecessarily increasing training parameters or relying on sequential operations.

In addition, according to an embodiment of the present invention, the time constant may be easily adjusted by adjusting the size of the capacitor 20 or the initial resistance values of the two nonvolatile memristors 11 and 12 as needed. Furthermore, since the mapping signal may be varied by adjusting the pulse shape of the input signal, utilization freedom degree of the temporal kernel device may be improved.

The temporal kernel device 100 according to an embodiment of the present invention may be configured to process time-series input signals (input information), to store information in the first and second nonvolatile memristors 11 and 12, and to input information stored in the first and second nonvolatile memristors 11 and 12 into an artificial neural network 200. In other words, information read after being stored in the first and second nonvolatile memristors 11 and 12 may be input to the artificial neural network 200. The information stored in the first and second nonvolatile memristors 11 and 12 may be input to the artificial neural network 200 as a form of, for example, a memristor conductance vector (MCV), and it is possible to determine what information is firstly input to the temporal kernel device 100 through information (data) processing/recognition of the artificial neural network 200.

A temporal kernel computing system according to an embodiment of the present invention may include the temporal kernel device 100 which is previously described, and the artificial neural network 200 connected to the temporal kernel element 100 and receiving information processed by the temporal kernel device 100. The specific configuration and the principles of the artificial neural network 200 may be the same or similar to those well known in the art.

A manufacturing method of a temporal kernel device according to an embodiment of the present invention will be briefly described as follows.

According to one example, when manufacturing a temporal kernel device, a capacitor, a second nonvolatile memristor, and a first nonvolatile memristor may be manufactured in the above order. First of all, a SiO₂ layer with about 100 nm thickness may be thermally formed on a Si substrate, and a TiN layer with about 80 nm thickness may be formed on the SiO₂ layer by sputtering at room temperature. The TiN layer may be patterned as a line shape as a lower electrode of the capacitor. The lower electrode of the capacitor may have a width of, for example, about 5 to 500 μm, and may be patterned using conventional photolithography and dry etching methods. Then, about 3 nm ZrO₂, about 2.5 nm Al₂O₃, and about 3 nm ZrO₂ may be sequentially deposited by using an atomic layer deposition (ALD) process at a substrate temperature of about 280° C. In other words, a ZAZ dielectric may be formed. Approximately 60 nm of TiN may be deposited on the ZAZ dielectric by sputtering, and the TiN and ZAZ dielectric may be patterned to form a capacitor including an upper electrode patterned from the TiN. After forming the capacitor, a first passivation layer having a thickness of about 80 nm may be deposited by using a plasma enhanced chemical vapor deposition (PECVD) process. The first passivation layer may be formed to cover the capacitor and may be formed by, for example, SiO₂. Then, TiN with a thickness of about 60 nm may be deposited by sputtering and patterned so that a lower electrode for a second nonvolatile memristor having a width of about 5 to 20 μm may be formed at a position next to the capacitor. Then, an HfO₂ film, which serves as a resistance change memory layer for the second nonvolatile memristor may be deposited to a thickness of about 2.5 nm by using a plasma enhanced atomic layer deposition (PEALD) process at a substrate temperature of about 280° C. Then, W (tungsten) with a thickness of about 40 nm is deposited by sputtering at room temperature, and W and HfO₂ film are patterned to form a second nonvolatile memristor. Next, a second passivation layer having a thickness of approximately 80 nm may be deposited. The second passivation layer may be formed to cover the capacitor and the second nonvolatile memristor, and may be formed as, for example, SiO₂. The second passivation layer and the first passivation layer may be wet-etched with a buffered oxide etchant (BOE) solution to expose the upper electrode of the capacitor and the upper electrode of the second nonvolatile memristor. Then, TiN with a thickness of about 60 nm may be deposited by sputtering and patterned to form an intermediate electrode with a width of about 5 to 20 μm. A portion of the intermediate electrode may be used as a lower electrode of the first nonvolatile memristor. Next, using the PEALD process, an HfO₂ film which serves as a resistance change memory layer for the first nonvolatile memristor may be deposited to a thickness of about 2.5 nm and patterned. W (tungsten) with a thickness of about 40 nm may be deposited by sputtering on the patterned HfO₂ film and patterned so that an upper electrode of the first nonvolatile memristor may be formed as a form of a line. However, the specific materials, device structure, process conditions, and the like mentioned in the manufacturing method of the temporal kernel device according to the above-described embodiment are merely examples and may vary in various ways.

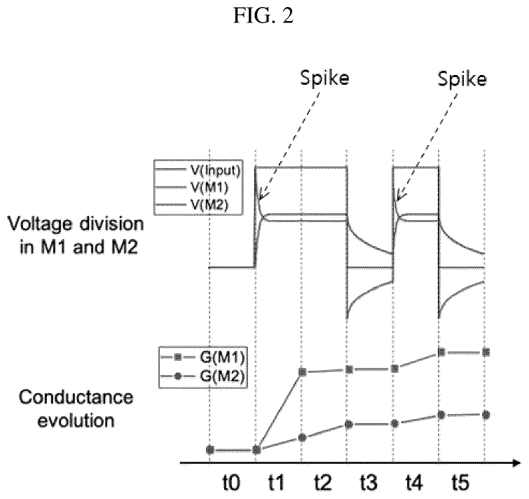

FIG. 2 is a diagram illustrating a change in the voltage applied to the first and second nonvolatile memristors (M1, M2) and a change in conductance of each memristor (M1, M2) according to the application of a temporal signal to the temporal kernel cell structure of the temporal kernel device according to an embodiment of the present invention. FIG. 2 shows the change in the voltage applied to each memristor (M1, M2) and conductance of each memristor (M1, M2) when the input signal corresponding to ‘1101’ (a low signal is ‘0’, and a high signal is ‘1’) is applied to the temporal kernel cell structure as a pulse stream according to time (t1 to t4).

Referring to FIG. 2, the input voltage will be distributed to the first nonvolatile memristor M1 and the second nonvolatile memristor M2 according to the dynamic relationship between the first and second nonvolatile memristors M1 and M2. Here, V(M1) represents the voltage applied to the first nonvolatile memristor M1, and V(M2) represents the voltage applied to the second nonvolatile memristor M2. VC which is the voltage of the capacitor C may be equal to V(M2). There may be a delay in charging and discharging the capacitor C due to the capacitive element and memristive resistance. This behavior causes a ‘peak and relaxation’ voltage pattern for M1 and an ‘increase and saturation’ pattern for M2 at a high signal (see a top graph), and as result of it, the conductance evolution of M1 and M2 may be different (see a bottom graph).

In the case of M1, when a high signal (‘1’) is input while the capacitor C is discharged, a spike (voltage spike) signal may be applied, and at this time, a tremendous increase in conductance may occur. The capacitor C may be in a discharging state at an initial time, and may be discharged when a low signal ‘0’ is input. Therefore, after the capacitor C is discharged by the low signal, when the high signal is input to the temporal kernel cell structure, a spike (voltage spike) signal may occur in M1. Therefore, it may be understood that M1 mainly reflects the number of transitions from a low signal to a high signal and related characteristics.

Meanwhile, in the case of M2, since a voltage similar to the input signal is applied, an increase in conductance may mainly occur when a high signal is input, and may be mainly affected by the number of inputs of high signal. Since M2 is mainly affected by the number of inputs of a high signal in a different way from M1, it may be said to reflect the number of inputs of a high signal and related characteristics in the input signal. Accordingly, M1 and M2 may perform unrelated (i.e., uncorrelated) individualized dimensional data mapping for the same input signal. In this regard, the level of data mapping may be increased and accuracy and efficiency of data processing may be improved.

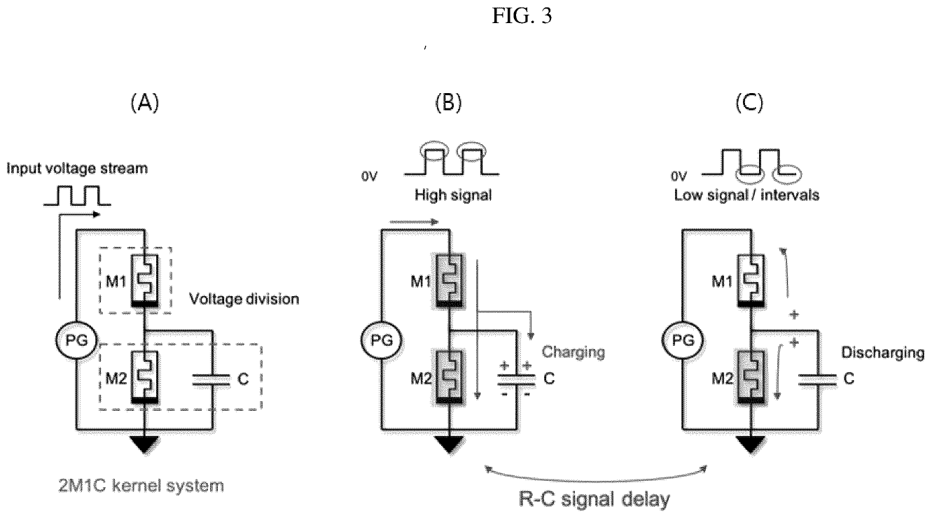

FIG. 3 is a circuit diagram for explaining an operation principle of a temporal kernel device according to an embodiment of the present invention.

Referring to FIG. 3, (A) diagram shows a circuit diagram of the temporal kernel cell structure. Here, the pulse generator PG may supply an input voltage stream to a device by using the grounded lower electrodes of M2 (second nonvolatile memristor) and C (capacitor). If a high signal is supplied while C is discharged, V(M1) may rapidly increase, and then decrease and become saturated, and V(M2) may gradually increase and become saturated as C is gradually charged with the high signal. When a low signal is subsequently applied, C may return to its original discharge state. As may be seen in (B) and (C) diagrams of FIG. 3, when temporal data is cascaded through the temporal kernel cell structure, high and low signals are repeated and charge/discharge RC delay occurs, and as a result, a distinct voltage pattern may be generated for M1 (the first nonvolatile memristor) and M2 (the second nonvolatile memristor). The input voltage may be distributed to M1 and M2, and a voltage spike may be generated in M1 due to RC delay, and a slowly increasing voltage may be applied to M2.

A voltage spike on M1 may only occur if C has previously discharged, and the voltage spike on M1 may be sensitive to a low signal (‘0’) coming before a high signal (‘1’). Conversely, as V(M2) increases with C charging, V(M2) may depend on the high signal (‘1’) itself. C may be discharged through M1 and M2 as shown in (C) diagram of FIG. 3. However, the current flowing through M1 and M2 may be different due to their different conductances, voltage-current nonlinearity, and bias polarity dependence. These characteristics may also enrich the final conductance states of M1 and M2, contributing to the high performance of the temporal kernel system. Therefore, M1 and M2 of the temporal kernel cell structure may provide a unique approach to temporal kernel computing by extracting and mapping complementary information for the same input.

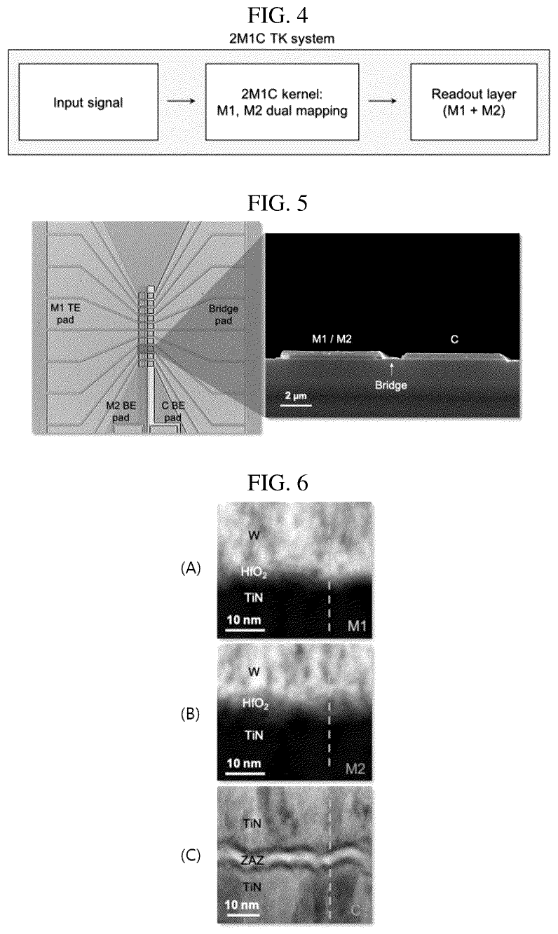

FIG. 4 is a diagram illustrating the overall operation method of a temporal kernel computing system including a temporal kernel device according to an embodiment of the present invention.

Referring to FIG. 4, in connection with a method of operating a temporal kernel computing system including a temporal kernel device according to an embodiment of the present invention, dual mapping may be performed by two nonvolatile memristors M1 and M2 by inputting an input signal to the temporal kernel device, and be projected onto two distinct conductance vectors. Then, combination and inference may be performed in a subsequent readout layer. The performance of a temporal kernel computing system may be verified through applications of, for example, image recognition and nonlinear time series prediction task. This will be explained in more detail later.

The operation method of the temporal kernel device according to an embodiment of the invention is summarized as follows. According to an embodiment of the present invention, there is provided an operation method of a temporal kernel device comprising one or more temporal kernel cell structures, wherein each of the temporal kernel cell structures includes a first nonvolatile memristor, and a second nonvolatile memristor and a capacitor connected in parallel with each other, and wherein the second nonvolatile memristor and the capacitor connected in parallel with each other are connected in series with the first nonvolatile memristor, the method comprising a step for storing information in the first and second nonvolatile memristors by applying a time-series input signal to the temporal kernel cell structure, and a step for reading information stored in the first and second nonvolatile memristors

Here, the temporal kernel device may be the same as described with reference to FIG. 1. Accordingly, the temporal kernel device may include a first electrode, a second electrode, an intermediate electrode, and a third electrode. The capacitor may be disposed between the first electrode and the intermediate electrode, the second nonvolatile memristor may be disposed between the second electrode and the intermediate electrode, and the first nonvolatile memristor may be disposed between the intermediate electrode and the third electrode.

The step for storing information in the first and second nonvolatile memristors may include a step for applying an electrical signal corresponding to the time-series input signal to the third electrode while the first and second electrodes are grounded. The step for reading information stored in the first and second nonvolatile memristors may include a step for applying an electrical signal for reading information stored in the first nonvolatile memristor between the third electrode and the intermediate electrode, and a step for applying an electrical signal for reading information stored in the second nonvolatile memristor between the intermediate electrode and the second electrode.

Furthermore, a plurality of the temporal kernel cell structures may be arranged to form an array. The temporal kernel device may include first and second electrodes spaced apart from each other and extending in a first direction, a plurality of third electrodes spaced apart from the first and second electrodes and extending in a second direction crossing (intersecting) the first and second electrodes, and a plurality of intermediate electrodes disposed between an electrode group consisting of the first and second electrodes and the plurality of third electrodes to correspond to the plurality of third electrodes, respectively. The plurality of temporal kernel cell structures may be disposed between the electrode group consisting of the first and second electrodes and the plurality of third electrodes, respectively. Each of the temporal kernel cell structures may include the capacitor disposed between the first electrode and the intermediate electrode, the second nonvolatile memristor disposed between the second electrode and the intermediate electrode, and the first nonvolatile memristor disposed between the intermediate electrode and the third electrode.

In addition, the operation method of the temporal kernel device may be understood based on the configuration and operation characteristics of the temporal kernel device described with reference to FIGS. 1 to 4. In addition, the operation method of a temporal kernel computing system to which a temporal kernel device according to the embodiment is applied may be easily understood.

FIG. 5 is a diagram illustrating an optical microscope image (left image) of a temporal kernel device and a cross-sectional scanning electron microscope (SEM) image (right image) of a temporal kernel cell structure according to an embodiment of the present invention.

Referring to FIG. 5, the structural connectivity of a temporal kernel cells having a 10×1-sized temporal kernel array device and a 2M-1C structure may be confirmed. M1 and M2 may be stacked vertically, and M2 and C may be spaced apart in the horizontal direction. Here, M1 TE pad represents the upper electrode pad of M1, Bridge pad represents the intermediate electrode pad, M2 BE pad represents the lower electrode pad of M2, and C BE pad represents the lower electrode pad of C. Furthermore, Bridge represents the intermediate electrode.

FIG. 6 is a diagram illustrating a cross-sectional transmission electron microscope (TEM) image of a first nonvolatile memristor M1, a second nonvolatile memristor M2, and a capacitor C which may be applied to a temporal kernel device according to an embodiment of the present invention. In FIG. 6, (A) diagram is a TEM image of M1, (B) diagram is a TEM image of M2, and (C) diagram is a TEM image of C. In FIG. 6 (C), ZAZ represents a stacked structure of ZrO₂/Al₂O₃/ZrO₂.

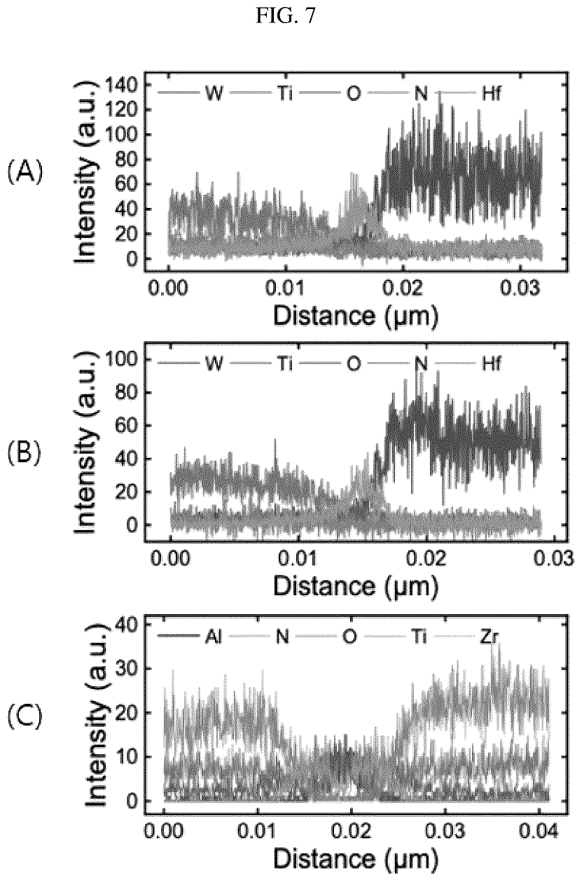

FIG. 7 is a diagram illustrating energy dispersive spectrometer (EDS) line profiles of a first nonvolatile memristor M1, a second nonvolatile memristor M2, and a capacitor C which may be applied to a temporal kernel device according to an embodiment of the present invention. Here, the line may correspond to the dotted line in FIG. 6. In FIG. 7, (A) diagram is illustrated for M1, (B) diagram is illustrated for M2, and (C) diagram is illustrated for C. However, the specific configuration and the materials of M1, M2, and C disclosed in FIGS. 6 and 7 are merely exemplary and may be varied in various ways.

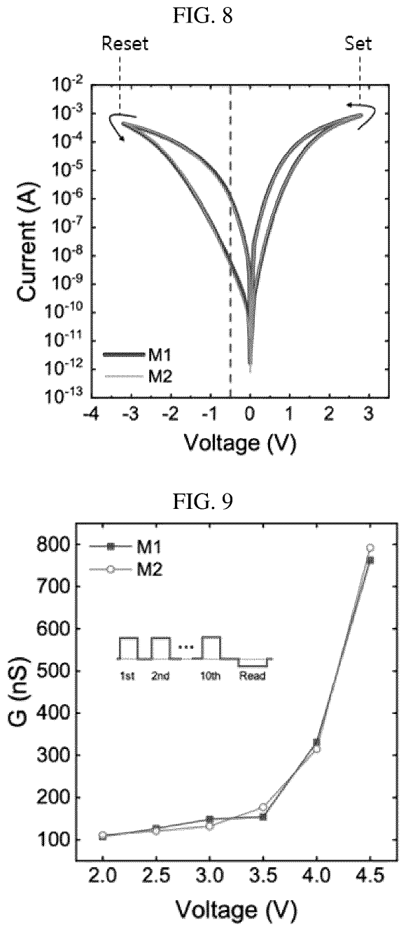

FIG. 8 is a graph illustrating voltage-current characteristics of the first and second nonvolatile memristors M1 and M2 which may be applied to a temporal kernel device according to an embodiment of the present invention. Here, the first and second nonvolatile memristors M1 and M2 have a TiN/HfO₂/W structure and have a size of 6 μm×6 μm. FIG. 8 shows the results evaluating sweep characteristics obtained by using direct current (DC) voltage. Furthermore, FIG. 8 shows evaluation results for each of the first and second nonvolatile memristors M1 and M2.

Referring to FIG. 8, the first and second nonvolatile memristors M1 and M2 which may be applied to the temporal kernel device according to an embodiment of the present invention may exhibit a voltage-current characteristics as shown according to a voltage sweep. When the voltage is swept in the positive (+) direction, set switching may occur as the current increases due to an increase in conductance. Meanwhile, when the voltage is swept in the negative (−) direction, reset switching in which the current decreases due to a decrease in conductance may occur. The first and second nonvolatile memristors M1 and M2 may exhibit substantially similar voltage-current characteristics. Furthermore, the first and second nonvolatile memristors M1 and M2 may have a wider memory window in the negative (−) voltage region, and for example, about −0.5 V may be selected as the read voltage for the conductance data. However, the characteristics of the first and second nonvolatile memristors M1 and M2 shown in FIG. 8 are exemplary and may be changed in various ways.

FIG. 9 is a graph illustrating the results obtained by measuring the final conductance after applying ten voltage pulses to the first and second nonvolatile memristors M1 and M2 which may be applied to the temporal kernel device according to an embodiment of the present invention. The dependence of the size of the voltage pulse was confirmed by gradually increasing the magnitude (height) of the voltage pulse. FIG. 9 shows evaluation results for each of the first and second nonvolatile memristors M1 and M2.

Referring to FIG. 9, in connection with the temporal kernel device according to an embodiment of the present invention, it may be confirmed that the conductance of the first and second nonvolatile memristors M1 and M2 increase non-linearly as the magnitude of the voltage pulse increases. These nonlinear characteristics may further improve responses and dimensionality of a kernel device.

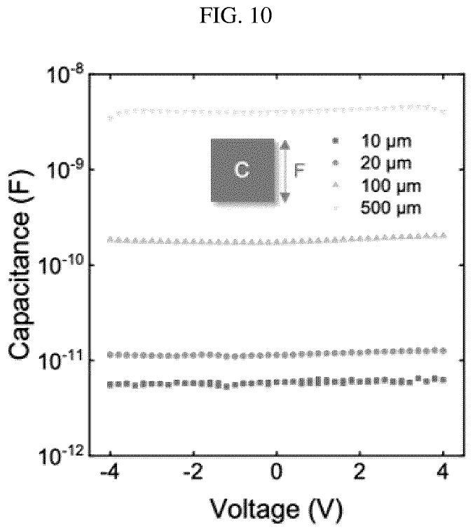

FIG. 10 is a graph illustrating capacitance values within a predetermined voltage range according to the feature size F of the capacitor C which may be applied to the temporal kernel device according to an embodiment of the present invention. Here, the feature size F of the capacitor C was 10, 20, 100, and 500 μm.

Referring to FIG. 10, it may be seen that the capacitor C has a stable capacitance value in a wide voltage range suitable for a kernel operation. When the feature size F of the capacitor C is 10 μm to 500 μm, a capacitance range of pF to nF may be obtained. A wide capacitance range with low leakage may be a desirable characteristic of a capacitor for a temporal kernel device.

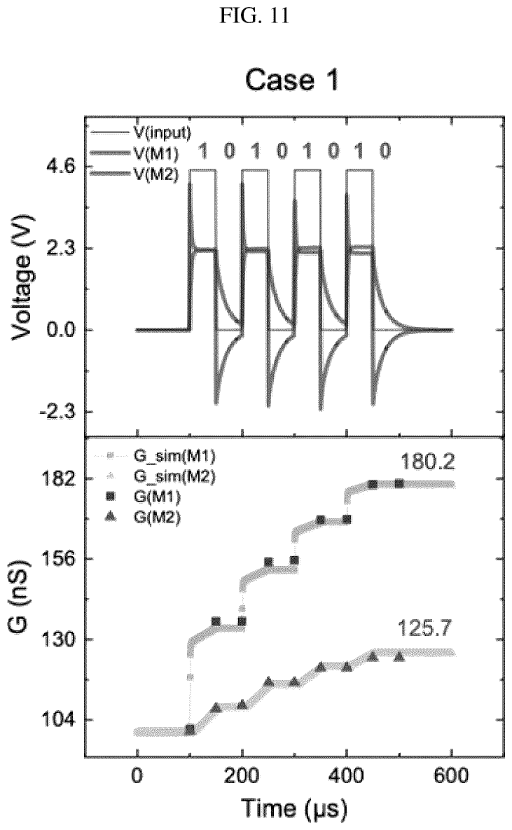

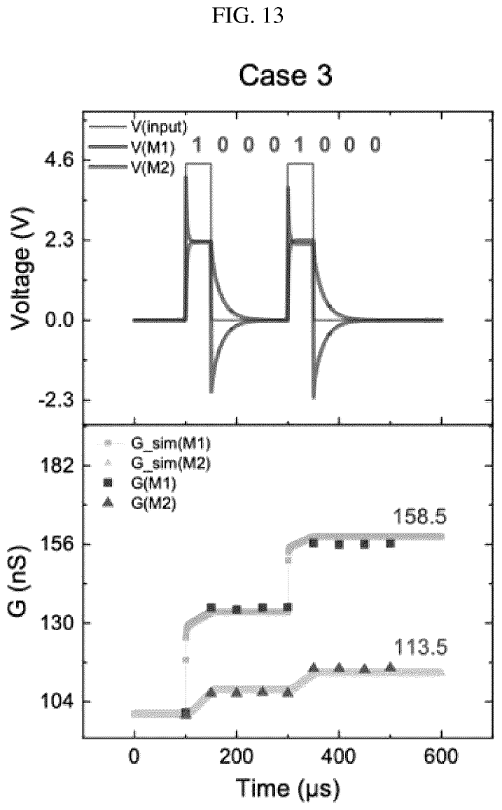

FIG. 11 to FIG. 13 are diagrams showing a change in voltage applied to the first and second nonvolatile memristors (M1, M2) and a change in conductance of each memristor (M1, M2) according to the application of an input signal to the temporal kernel device according to an embodiment of the present invention. FIG. 11 to FIG. 13 show kernel responses to three different 8-bit binary input signals: ‘10101010’ (case 1), ‘11001100’ (case 2), and ‘10001000’ (case 3). Each binary input signal was input as a form of a voltage pulse stream. V(M1) represents the voltage applied to the first nonvolatile memristor M1, V(M2) represents the voltage applied to the second nonvolatile memristor M2, and G(M1) represents the conductance of the first nonvolatile memristor M1, and G(M2) represents the conductance of the second nonvolatile memristor M2. FIG. 11 to FIG. 13 also include conductance data [G_sim(M1), G_sim(M2)] measured by simulation. G_sim(M1) is a data for the first nonvolatile memristor M1, and G_sim(M2) is a data for the second nonvolatile memristor M2. In the measurements of FIGS. 11 to 13, the capacitance of the capacitor C was set to 150 pF.

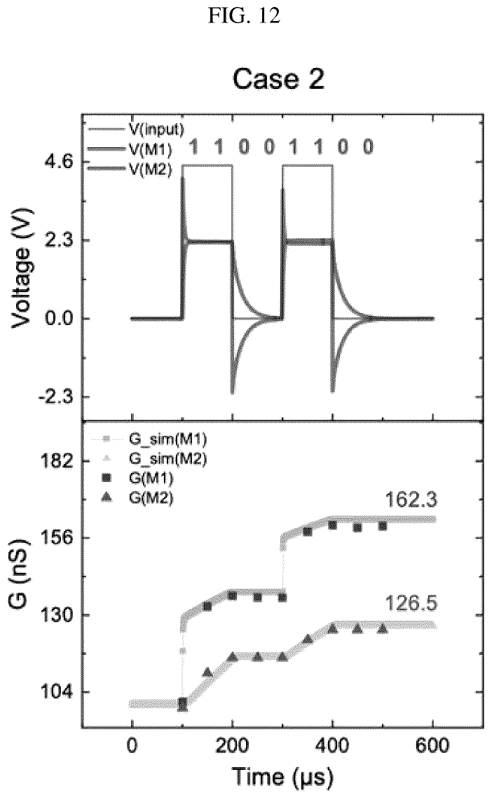

Referring to FIGS. 11 to 13, as described above, V(M1) may exhibit a ‘peak and relaxation’ pattern only when C (capacitor) is previously discharged, and V(M2) may exhibit ‘increase and saturation’ pattern for a signal ‘1’. For example, it may be seen that there is no peak in V(M1) for the second and the fourth ‘1’ in the ‘11001100’ input pattern of FIG. 12. Both of V(M1) and V(M2) have a saturation region during the signal ‘1’, but as described with reference to FIG. 9, M1 may be sensitive more in the ‘peak’ region due to the non-linear conductance change of M1 and M2 with respect to voltage. M1 may be more sensitive to signal ‘0’ before a consecutive ‘1’ (relatively insensitive to repeated ‘1’), and M2 may be more sensitive to signal ‘1’ itself due to this unique voltage distribution and nonlinear dependency characteristic.

As may be seen in the conductance data (bottom graphs), M1 showed the highest final conductance in case 1, which generated a total of 4 spikes due to repeated signal ‘0’ between signal ‘1’. Since only two spikes occur in cases 2 and 3, the conductance of M1 becomes lower than that in case 1. Meanwhile, M2 shows a high value as four ‘1’s are given in case 1 and case 2, but in case 3, two ‘1’s are given, resulting in a low conductance value. Accordingly, M1 and M2 may extract complementary information from the input signal to achieve separability of each pattern (input pattern), which may not be achieved with a single memristive device.

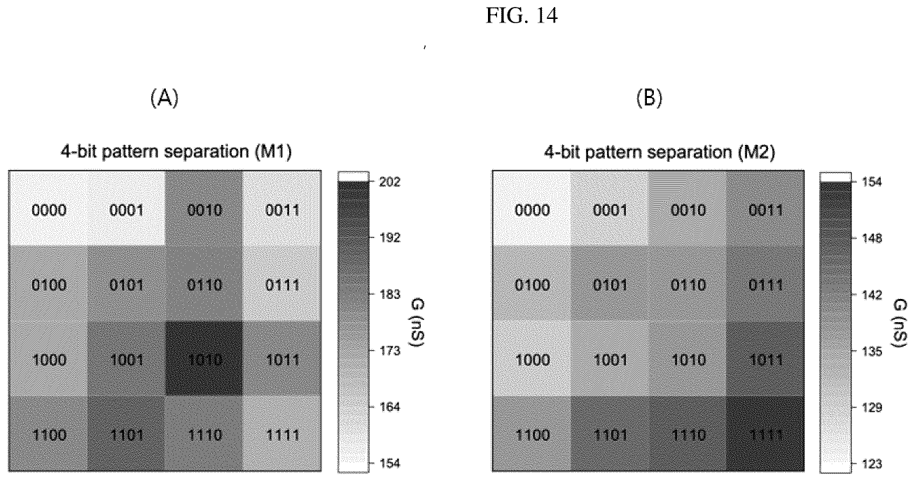

FIG. 14 is a diagram illustrating the final conductance state measured in the first nonvolatile memristor M1 and the second nonvolatile memristor M2 for 16 cases of 4-bit patterns from ‘0000’ to ‘1111’ according to an embodiment of the present invention. (A) diagram in FIG. 14 shows the results for the first nonvolatile memristor M1, and (B) diagram shows the results for the second nonvolatile memristor M2. The pulse conditions were 5 V height and 50 μs width, and the capacitance was 150 μF. For temporal separation, a reference ‘1’ signal was provided at the end of each sequence (otherwise the results of ‘0101’ and ‘1010’ inputs would be the same). That is, a reference ‘1’ signal was added to the end of all sequences in (A) and (B) of FIG. 14. In FIG. 14, the reference signal ‘1’ is not indicated.

Referring to FIG. 14, in the case of M1, ‘0000’, ‘0001’, ‘0011’, ‘0111’, and ‘1111’ were single spike throughout the sequence, and belonged to the low conductance group, and the ‘1010’ pattern was shown as three spikes, and exhibited the highest conductance value. Meanwhile, M2 showed higher conductance as the number of signal ‘1’s increased.

To further investigate the kernel characteristics, various capacitances and signal voltages were tested, which may affect the temporal dynamics and nonlinearities of the integrated system. For the 4-bit input case, the final conductance values of M1 and M2 were evaluated when C changed from 20 pF, 150 pF to 1000 pF, respectively. As capacitance increases, the conductance values of both M1 and M2 increase. The main reason of it is as follows. As the larger capacitance is accompanied by a longer spike relaxation time in M1, duration may be prolonged in the higher voltage region. The increased conductance value for M1 in the peak region may result in lower V(M1) in the subsequent saturation region. Then, V(M2) increases, and the conductance of M2 may increase accordingly. However, delayed discharge of C which has a higher capacitance value may lower the spike amplitude for the next ‘1’ depending on the number of ‘0’s. Due to this complex relationship, the characteristics of M1 connected to 1000 pF C may vary depending not only on the number of spikes but also on the interval between signal ‘1’s. A longer interval between signal ‘1’s may cause C to fully discharge, and as a result, the second spike may become higher. On the other hand, if the C capacitance is too small (about 20 pF), the voltage spike to increase the conductance of M1 may not be effectively generated. This may be because the capacitor C is charged momentarily at the beginning of signal ‘1’.

Furthermore, the voltage dependence (4, 5, and 6 V) of M1 and M2 mapping characteristics was evaluated. In case of M1, when increasing a voltage, it increases more rapidly and non-linearly, and thus, the inputs with different peak numbers may be better distinguished. When lowering the voltage, the effects of spike and saturation voltages become similar, which may result in somewhat lower differences between the M1 and M2 mapping schemes. Therefore, it is necessary to appropriately select operating conditions and device capabilities for the desired mapping. Nonetheless, the tunable dynamics of the temporal kernel device according to embodiments may improve the dimension of feature-extracting ability.

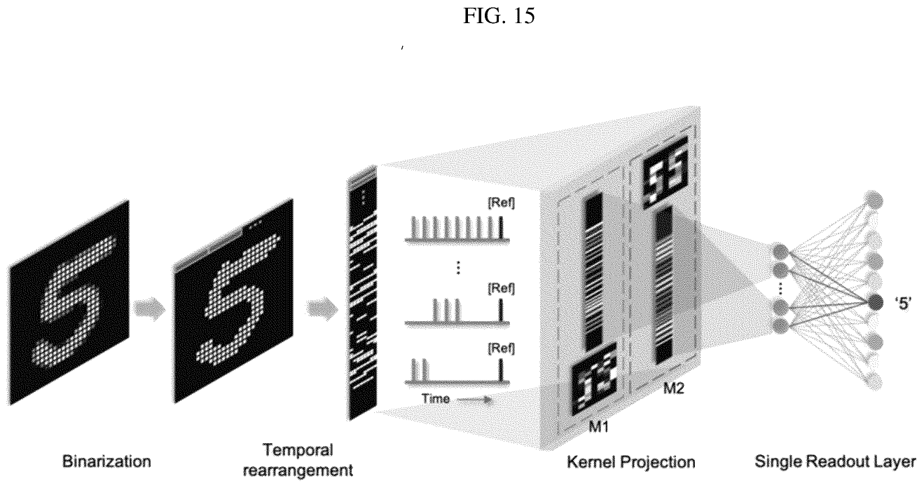

FIG. 15 is a schematic diagram illustrating an image inference process using a temporal kernel computing system including a temporal kernel device according to an embodiment of the present invention.

Referring to FIG. 15, the raw data may be preprocessed and transferred to the temporal domain, projected by a 2M-1C temporal kernel device, and may be further trained and inferred in the final readout network. The raw MNIST image consisting of 784 pixels (28×28) may be binarized into ‘0’ and ‘1’. Then, the binary pixels may be chopped into 8-bit sequences (784/8=98 units) and rearranged in the temporal domain to form the input pulse stream for feeding the kernel. These input streams may be fed to the kernel and expected to be the final conductances of M1 and M2. These values represent a higher dimensional space as a more distilled and condensed form, but the actual volume of the data itself may be reduced. Next, a conductance vector consisting of 196 values (M1 and M2 data from 98 units) may be input to the read inference layer (single layer). In case of the 10, 14, and 28-bit sequences, the processes are performed similarly but smaller units and input sizes (78, 56, and 28 units and 156, 112, and 56 readout input sizes, respectively) are used for readout. Without burdening the entire learning network, only a single feedforward layer network directly connecting the classes which are inferred from ‘0’ to ‘9’ may be used. Since the MNIST dataset has 10 numeric classes, there are only 1960, 1560, 1120, and 560 parameters to train for each of the 8, 10, 14, and 28-bit cases, which means that the size of the network parameters is quite (surprisingly) small.

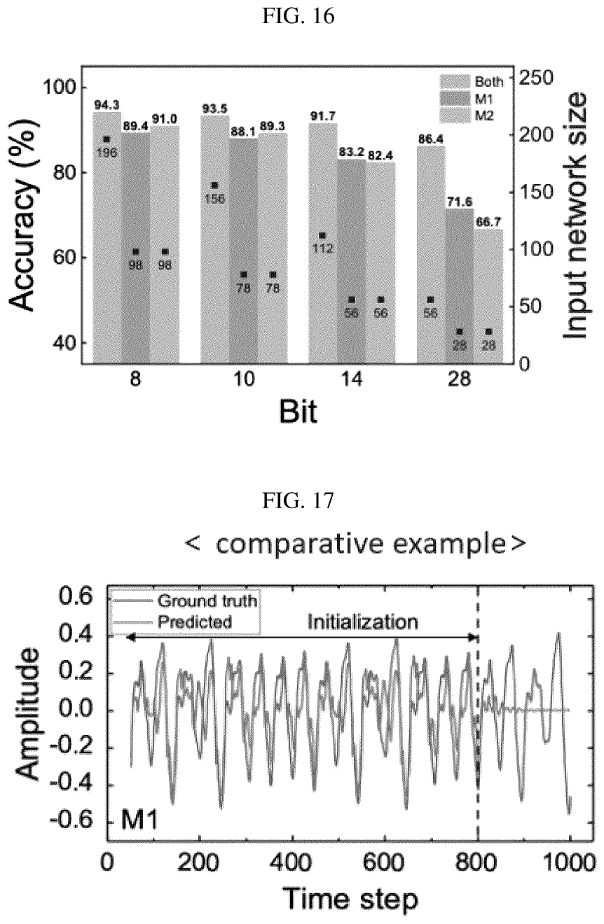

FIG. 16 is a graph illustrating the maximum accuracy and input network size achieved under the condition of each input sequence when image inference is performed using a temporal kernel computing system including a temporal kernel device according to an embodiment of the present invention. FIG. 16 shows a maximum accuracy and an input network size achieved under the conditions (pulse 5V/50 μs, C=150 pF for 8, 10, and 14-bit cases, C=1000 pF for 28-bit case) which are given for each inference case of 8, 10, 14, and 28-bit input sequences. The result indicated as “Both” in FIG. 16 uses both data from M1 and M2, and corresponds to an embodiment of the present invention. Meanwhile, the result indicated as “M1” is a case where inference is performed by using only the data of M1, and the result indicated as “M2” is a case where the inference is performed by using only the data of M2. Therefore, the “M1” and “M2” cases correspond to comparative examples.

Referring to FIG. 16, it may be seen that 94.3% and 86.4% accuracy was achieved in the 8-bit and 28-bit cases. Accuracy and unit bits may have a trade-off relationship. As the number of bits increases, accuracy may decrease. Nevertheless, an accuracy of 86.4% may be a terribly high result even with a small number of training parameters 560 for a very long 28-bit pattern. Furthermore, when both M1 and M 2 were used, the accuracy in all cases was found to be the highest compared to the case of single M1 or M2. It may be seen that the longer the pattern, the greater the complementarity between M1 and M2, resulting in a greater increase in accuracy when both M1 and M2 are adopted. Since no improvement in accuracy is expected from just combining arbitrary data, the improvement in accuracy when using both of M1 and M2 means that the features mapped by M1 and M2 are not linearly correlated, but rather are distinct from each other.

FIG. 17 is a diagram illustrating the results of initialization and prediction by using only the conductance vector of the first nonvolatile memristor M1 in Mackey-Glass time series prediction according to a comparative example. Here, a 10×1 network was trained with data ranging from 1 to 800 steps, and prediction was performed without an update process for 200 steps.

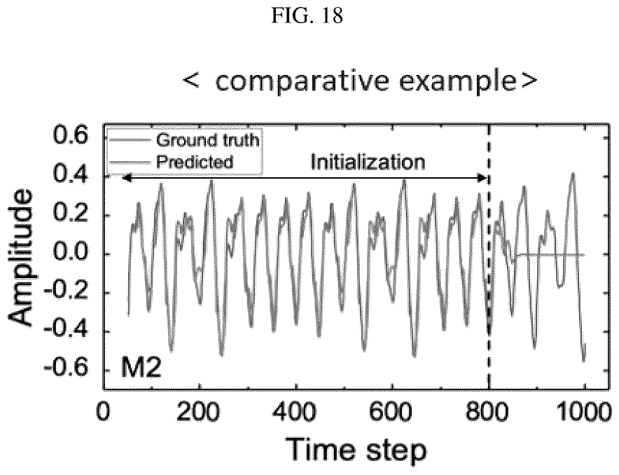

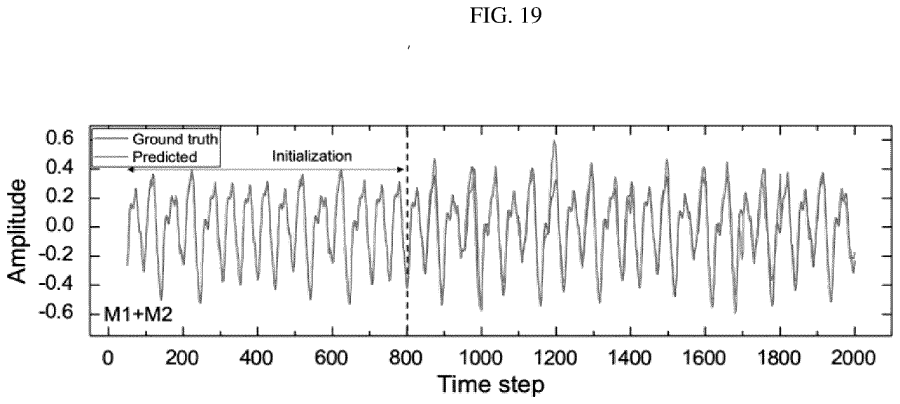

FIG. 18 is a graph illustrating the results of initialization and prediction performed by using only the conductance vector of the second nonvolatile memristor M2 in Mackey-Glass time series prediction according to a comparative example. Here, a 10×1 network was trained with data ranging from 1 to 800 steps, and prediction was performed without an update process for 200 steps. In FIGS. 17 and 18, “Ground truth” represents actual data, and “Predicted” represents predicted values. Furthermore, initialization refers to the learning phase.

Referring to FIG. 17 and FIG. 18, when learning and prediction are performed by using only the conductance vector of the first nonvolatile memristor M1 or the conductance vector of the second nonvolatile memristor M2, it may be confirmed that the accuracy of prediction is remarkably reduced.

FIG. 19 is a graph illustrating the results obtained by performing initialization and prediction by using both of the conductance vector of the first nonvolatile memristor M1 and the conductance vector of the second nonvolatile memristor M2 in Mackey-Glass time series prediction, according to an embodiment of the present invention. After initializing up to 800 steps, a prediction process was performed for 1200 steps through a 100-step prediction and 50-step update cycle.

Referring to FIG. 19, successful learning and prediction may be achieved by using the MCV (memristor conductance vector) of M1 and M2 together according to an embodiment of the present invention. The initialization and the prediction steps have normalized root mean square error (NRMSE) of 0.023 (800 steps) and 0.026 to 0.06 (50 to 150 steps), respectively. Long-range prediction was also successful with low NRMSE by updating 50 steps per 100 prediction steps. For Mackey-Glass time series prediction using the 2M-1C kernel, a very small single layer readout network with 20×1 dimension which is 50 to 100 times smaller than previous studies was used. Here, in a 20×1 readout network, 20 may correspond to the total number of memristors (i.e., the total number of first and second nonvolatile memristors), and 1 may correspond to the number of neuron device. This performance may be achieved because of the following reason. As the information mapped to memristors M1 and M2 are not correlated (i.e., uncorrelated), a sufficiently large feature space is secured with only two memristors.

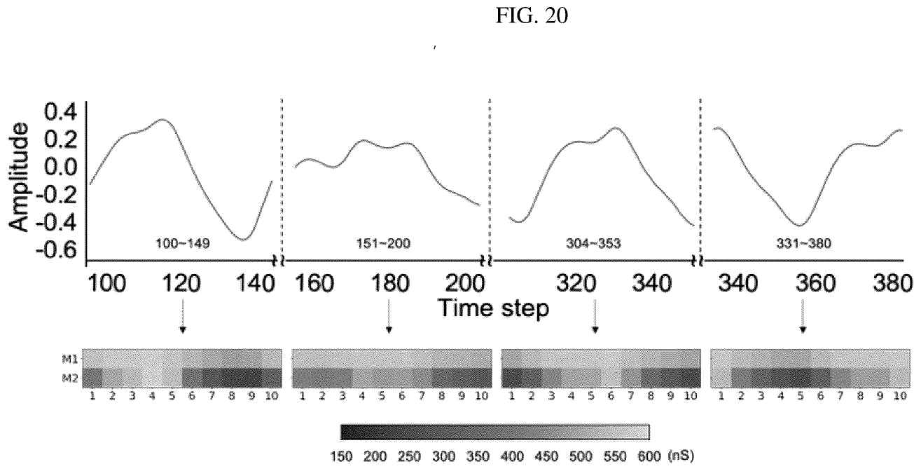

FIG. 20 is a diagram illustrating the results obtained by evaluating the conductance values for four types of time series patterns to analyze information extracted from the time series of the first nonvolatile memristor M1 and the second nonvolatile memristor M2 according to an embodiment of the present invention. The upper graphs in FIG. 20 correspond to a portion of FIG. 19. The lower mapping diagrams in FIG. 20 show the conductance data mapped to M1 and M2 for each of the upper graphs.

Referring to FIG. 20, the conductance of M1 and M2 may vary depending on an amplitude and a duration of each application voltage determined by the kernel condition and time series pattern. Each time series of 50-time steps may be applied as an analog voltage to 10 kernels (kernel cells) at 5-time steps. M1 and M2 may reflect the characteristics of the time series in different ways. As a result, M1 and M2 may contribute to the kernel system's performance to identify overall trends and local variations within a time series.

According to the embodiments of the present invention described above, it is possible to implement a temporal kernel device which may achieve high dimensional data mapping and tunable dynamics by using a 2M (memristor)-1C (capacitor) temporal kernel cell structure including two nonvolatile memristors and one capacitor. According to embodiments of the present invention, the object of the present invention is to provide a temporal kernel device which may improve diversity of reservoir states, and may perform efficient and accurate data processing with high dimensionality and tunable dynamics without unnecessarily increasing training parameters or relying on sequential operations.

In particular, according to embodiments of the present invention, since two nonvolatile memristors may perform uncorrelated individualized dimensional data mapping for the same input signal, the dimensionality of data mapping may be increased and the accuracy and efficiency of data processing may be improved. Furthermore, if necessary, the time constant may be easily adjusted by adjusting the size of the capacitor or adjusting the initial resistance values of the two nonvolatile memristors. Furthermore, since the mapping signal may be varied by adjusting the pulse shape of the input signal, utilization freedom degree of the device may be improved.

According to one embodiment, the complementary features projected on each memristor reflect the features of the binary pattern of the input signal, and in the MNIST (Modified National Institute of Standards and Technology) classification task, it may achieve an accuracy of about 94.3% or more and about 86.4% or more in the 8-bit and 28-bit cases, respectively. Furthermore, according to one embodiment, for Mackey-Glass nonlinear timeseries patterns, since the temporal kernel device may exhibit a normalized root mean square error (NRMSE) of 0.04 at the minimum network size (20×1), it may be said that excellent prediction performance has been verified.

It is possible to implement a temporal kernel computing system which has excellent performance and may be applied to various fields by applying the temporal kernel device according to the above-described embodiments.

In this specification, the preferred embodiments of the present invention have been disclosed, and although specific terms have been used, they are only used in a general sense to easily explain the technological content of the present invention and to help understanding the present invention, and they are not used to limit the scope of the present invention. It is obvious to those having ordinary skill in the related art to which the present invention belong that other modifications based on the technological idea of the present invention may be implemented in addition to the embodiments disclosed herein. It will be understood to those having ordinary skill in the related art that in connection with a temporal kernel device, and a temporal kernel computing system including the same and their operating methods according to the embodiments described with reference to FIGS. 1 to 16 and FIGS. 19 and 20, various substitutions, changes, and modifications may be made without departing from the technological spirit of the present invention. Therefore, the scope of the invention should not be determined by the described embodiments, but should be determined by the technological concepts described in the claims.

### INDUSTRIAL APPLICABILITY

The embodiments of the present invention may be applied to kernel-related devices and systems, and the methods related thereto. The embodiments of the present invention may be applied to a temporal kernel device, a temporal kernel computing system including the same, and operation methods thereof.

1. A temporal kernel device comprising:
one or more temporal kernel cell structures,
wherein each of the temporal kernel cell structures includes:
a first nonvolatile memristor; and
a second nonvolatile memristor and a capacitor connected in parallel with each other,
wherein the second nonvolatile memristor and the capacitor connected in parallel with each other are connected in series with the first nonvolatile memristor.

2. The temporal kernel device of claim 1,
wherein the temporal kernel device comprises a first electrode, a second electrode, an intermediate electrode, and a third electrode,
wherein the capacitor is disposed between the first electrode and the intermediate electrode, the second nonvolatile memristor is disposed between the second electrode and the intermediate electrode, and the first nonvolatile memristor is disposed between the intermediate electrode and the third electrode.

3. The temporal kernel device of claim 2, wherein the temporal kernel device is configured so that an electrical signal corresponding to a time-series input signal is applied to the third electrode while the first and second electrodes are grounded.

4. The temporal kernel device of claim 1,
wherein a plurality of the temporal kernel cell structures are arranged to form an array,
wherein the temporal kernel device includes first and second electrodes spaced apart from each other and extending in a first direction, a plurality of third electrodes spaced apart from the first and second electrodes and extending in a second direction crossing the first and second electrodes, and a plurality of intermediate electrodes disposed between an electrode group consisting of the first and second electrodes and the plurality of third electrodes to correspond to the plurality of third electrodes, respectively,
wherein the plurality of temporal kernel cell structures are disposed between the electrode group consisting of the first and second electrodes and the plurality of third electrodes, respectively,
wherein each of the temporal kernel cell structures includes the capacitor disposed between the first electrode and the intermediate electrode, the second nonvolatile memristor disposed between the second electrode and the intermediate electrode, and the first nonvolatile memristor disposed between the intermediate electrode and the third electrode.

5. The temporal kernel device of claim 1,
wherein the first and second nonvolatile memristors are arranged on the same vertical axis,
wherein the capacitor is arranged to be spaced apart from the second nonvolatile memristor in a horizontal direction.

6. The temporal kernel device of claim 1, wherein the first and second nonvolatile memristors are configured to store different information for the same input signal.

7. The temporal kernel device of claim 1, wherein the temporal kernel device is configured to store information in the first and second nonvolatile memristors and to input the information stored in the first and second nonvolatile memristors to an artificial neural network.

8. A temporal kernel computing system comprising:
the temporal kernel device of claim 1; and
an artificial neural network connected to the temporal kernel device and receiving information processed by the temporal kernel device.

9. An operation method of a temporal kernel device including one or more temporal kernel cell structures, wherein each of the temporal kernel cell structures includes a first nonvolatile memristor, and a second nonvolatile memristor and a capacitor connected in parallel with each other, and wherein the second nonvolatile memristor and the capacitor connected in parallel with each other are connected in series with the first nonvolatile memristor, comprising:
storing information in the first and second nonvolatile memristors by applying a time-series input signal to the temporal kernel cell structure; and
reading information stored in the first and second nonvolatile memristors.

10. The operation method of a temporal kernel device of claim 9, wherein the temporal kernel device includes a first electrode, a second electrode, an intermediate electrode, and a third electrode, the capacitor is disposed between the first electrode and the intermediate electrode, the second nonvolatile memristor is disposed between the second electrode and the intermediate electrode, and the first nonvolatile memristor is disposed between the intermediate electrode and the third electrode.

11. The operation method of a temporal kernel device of claim 10, wherein the storing information in the first and second nonvolatile memristors includes applying an electrical signal corresponding to the time-series input signal to the third electrode while the first and second electrodes are grounded.

12. The operation method of a temporal kernel device of claim 10, wherein the reading information stored in the first and second nonvolatile memristors includes applying an electrical signal for reading information stored in the first nonvolatile memristor between the third electrode and the intermediate electrode, and applying an electrical signal for reading information stored in the second nonvolatile memristor between the intermediate electrode and the second electrode.

13. The operation method of a temporal kernel device of claim 9,
wherein a plurality of the temporal kernel cell structures are arranged to form an array,
wherein the temporal kernel device includes first and second electrodes spaced apart from each other and extending in a first direction, a plurality of third electrodes spaced apart from the first and second electrodes and extending in a second direction crossing the first and second electrodes, and a plurality of intermediate electrodes disposed between an electrode group consisting of the first and second electrodes and the plurality of third electrodes to correspond to the plurality of third electrodes, respectively,
wherein the plurality of temporal kernel cell structures are disposed between the electrode group consisting of the first and second electrodes and the plurality of third electrodes, respectively,
wherein each of the temporal kernel cell structures includes the capacitor disposed between the first electrode and the intermediate electrode, the second nonvolatile memristor disposed between the second electrode and the intermediate electrode, and the first nonvolatile memristor disposed between the intermediate electrode and the third electrode.
